(19) United States
(12) Patent Application Publication
(10) Pub. No.: US 2006/0148157 A1
(43) Pub. Date: Jul. 6, 2006

(54) Geometrically optimized spacer to improve device performance

(75) Inventors: Hun-Jan Tao, Hsinchu (TW); Ju-Wang Hsu, Taipei City (TW); Mong-Song Liang, Hsin-Chu (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 11/026,010

(22) Filed: Dec. 31, 2004

(51) Int. Cl. H01L 21/8238

(52) U.S. Cl. 438/199

(57) ABSTRACT

A CMOS device with trapezoid shaped spacers and a method for forming the same with improved critical dimension control and improved salicide formation, the CMOS device including a semiconductor substrate; a gate structure comprising a gate dielectric on the semiconductor substrate and a gate electrode on the gate dielectric; trapezoid shaped spacers adjacent either side of the gate structure; wherein, the trapezoid shaped spacers have a maximum height at an inner edge adjacent the gate electrode lower than an upper portion of the gate electrode to expose gate electrode sidewall portions.

### FIELD OF THE INVENTION

This invention generally relates to processes for forming semiconductor devices including CMOS and MOSFET devices and more particularly to CMOS device spacers and a manufacturing method for forming the same to improve device performance including improved gate electrode electrical contact resistance (Rs).

### BACKGROUND OF THE INVENTION

As MOSFET and CMOS device characteristic sizes are scaled below 0.1 microns including below 45 nm, the process window for wet and dry etching processes are increasingly difficult to control to achieve desired critical dimensions. For example, in forming dielectric spacers, also referred to as sidewall spacers or main spacers, it is particularly difficult to control the width of the spacers, especially when subjected to subsequent self aligned silicide (salicide) formation processes. For example, the width of a spacer may be as small as 600 Angstroms (60 nanometers) or less in 65 nanometer critical dimension (gate length) CMOS devices.

According prior art processes, spacers are formed adjacent either side of the gate structure (gate dielectric and gate electrode) and serve to align the formation of source/drain regions whereby the spacers act as an ion implant shield to form a relatively higher doping level of N or P-type doping over source/drain (S/D) regions. The S/D regions are aligned adjacent a previously formed lower doping level source drain extension (SDE) region, also referred to as an LDD region, formed adjacent the channel region underlying the gate dielectric.

As device characteristic (critical) dimensions shrink, achieving close dimensional tolerances of spacers is critical to achieving reliable electric performance and avoiding short channel effects (SCE) . For example, SDE regions affect SCE according to both depth and width of the SDE doped region. The width of the spacers determines at least the width of the SDE regions. Spacer formation typically requires both deposition and etching processes, for example, first depositing and subsequently removing portions of deposited dielectric layers. As device sizes decrease below about 0.13 microns, both the deposition process and the etching process have extremely narrow process windows whereby dimensional variations undesirably alter critical dimensions (CD's) and electrical performance of the CMOS device.

Generally, spacers used in conjunction with subsequent salicide formation processes, including over an uppermost portion of the gate electrode and source/drain regions, have been formed in a triangular or L-shaped geometrical configuration. Problems with theses geometrical configurations include the shortcomings that the width of L-shaped spacers are extremely difficult to control to achieve widths within design rule criteria, including device pitch considerations. For example, the bottom portion of the L-shaped spacer is easily altered in etching processes, whereby a small (e.g., a few nanometers) variation in width overlying the SDE region results in a large percentage variation according to design rules, thereby detrimentally affecting device performance.

On the other hand, triangular shaped spacers, which do not have vertically disposed sidewalls, have the shortcoming that in a subsequent etching process, the exposed sidewalls of the spacers are exposed to the etching process, thereby undesirably altering the width of the triangular shaped spacer.

There is therefore a need in the semiconductor integrated circuit manufacturing art for an improved spacer and method for forming the same to achieve a more robust spacer to avoid the width altering effects of subsequent etching processes, thereby improving device performance.

It is therefore among the objects of the present invention to provide an improved spacer and method of forming the same to achieve a more robust spacer to avoid the width altering effects of subsequent etching processes, thereby improving device performance, in addition to overcoming other shortcomings of the prior art.

### SUMMARY OF THE INVENTION

To achieve the foregoing and other objects, and in accordance with the purposes of the present invention, as embodied and broadly described herein, the present invention provides a CMOS device with trapezoid shaped spacers and a method for forming the same with improved critical dimension control and improved salicide formation.

In a first embodiment, the CMOS device includes a semiconductor substrate; a gate structure comprising a gate dielectric on the semiconductor substrate and a gate electrode on the gate dielectric; trapezoid shaped spacers adjacent either side of the gate structure; wherein, the trapezoid shaped spacers have a maximum height at an inner edge adjacent the gate electrode lower than an upper portion of the gate electrode to expose gate electrode sidewall portions.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1D are cross sectional views of a portion of a CMOS transistor showing exemplary integrated circuit manufacturing stages according to an embodiment of the present invention.

FIG. 2 is a process flow diagram including several embodiments of the present invention.

### DETAILED DESCRIPTION OF THE PREFERRED EMBODIMENTS

Although the method of the present invention is explained by reference to an exemplary CMOS transistor where the method of the present invention may be advantageously used, it will be appreciated that the method and spacers of the present invention may be used in any CMOS transistor or MOSFET structure where the width of the spacers is resistant to width reduction in subsequent etching processes including dry etching.

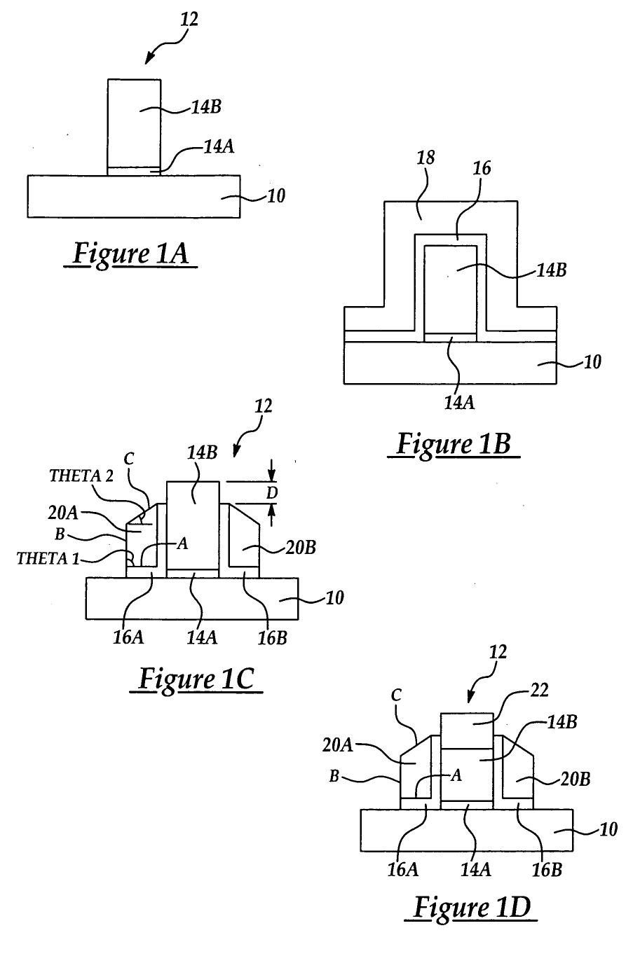

Referring to FIG. 1A is shown an exemplary implementation of the method of the present invention. Shown is a semiconductor substrate 10, having an overlying CMOS gate structure 12, including a gate dielectric portion 14A and overlying gate electrode portion 14B. Gate dielectric portion 14A and overlying gate electrode portion 14B are formed by conventional deposition, lithographic and etching processes. The substrate 10, for example, may include, but is not limited to, silicon, silicon on insulator (SOI), stacked SOI (SSOI), stacked SiGe on insulator (S-SiGeOI), SiGeOI, and GeOI, or combinations thereof.

Still referring to FIG. 1A, the gate structure including gate dielectric portion 14A and gate electrode portion 14B may be formed by conventional CVD deposition, lithographic patterning, and plasma and/or wet etching methods known in the art. The gate dielectric 14A may be formed by any process known in the art, e.g., thermal oxidation, nitridation, sputter deposition, or chemical vapor deposition. The gate dielectric may include silicon oxide, silicon nitride, silicon oxynitride, high-K (e.g., K>8) dielectrics including transition metal oxides and rare earth metal oxides. For example, the gate dielectric may include aluminum oxide (Al₂O₃), hafnium oxide (HfO₂), hafnium oxynitride (HfON), hafnium silicate (HfSiO₄), zirconium oxide (ZrO₂), zirconium oxynitride (ZrON), zirconium silicate (ZrSiO₂), yttrium oxide (Y₂O₃), lanthanum oxide (La₂O₃), cerium oxide (CeO₂), titanium oxide (TiO₂), tantalum oxide (Ta₂O₅), or combinations thereof. The gate length of the CMOS device is preferably less than about 65 nm and the thickness of the gate dielectric is less than about 10 nm.

The gate electrode portion e.g., 14B of the gate structure is preferably formed of a material compatible with a subsequent metal silicide, e.g., polycide formation process, for example formed of polysilicon, amorphous polysilicon, doped polysilicon, and polysilicon-germanium, or combinations thereof.

For example, a gate dielectric layer is first formed over the substrate 10 by CVD, sputtering or thermal growth processes followed by deposition of an overlying gate electrode layer and a hardmask layer. Conventional lithographic patterning and dry etching processes are then carried out to form the gate structure 12. A first ion implant is carried out to form doped regions (not shown) in the semiconductor substrate e.g., SDE regions adjacent either side of the gate structure 12.

Referring to FIG. 1B, an oxide layer 16, is then blanket deposited over the gate structure 12. The oxide layer 16 is preferably formed by a CVD process, for example a PECVD or LPCVD process, preferably having a thickness of from about 75 Angstroms to about 150 Angstroms. Preferably, the silicon oxide layer 16 is formed using a tetraethylorthosilicate (TEOS) precursor and a source of oxygen, preferably ozone (O₃) or a mixture of O₂/O₃, but other forms of silicon oxide may be used as well. A furnace or rapid thermal anneal (RTA), may be carried out following formation of the oxide layer 16, preferably between about 800 and about 1100° C. to densify the oxide layer and activate the ion implanted dopants.

A silicon containing layer 18, preferably nitride containing, such as silicon nitride(e.g., Si₃N₄, SiN), Si-rich N, silicon oxynitride (e.g., SiOₓN_{y}), si-rich ON, or combinations thereof, is then blanket deposited over the oxide layer 16, e.g., by a LPCVD or PECVD process, at a thickness greater than about 300 Angstroms, preferably at a temperature less than about 700° C. For example, silane and/or chlorosilane precursors such as silane (SiH₄), disilane (Si₂H₆), trisilane (Si₃H₈), dichlorosilane (SiH₂Cl₂), trichlorosilane (SiHCl₃), hexacholorodisilane (Si₂Cl₆), and the like, or mixtures thereof may be use to form the nitride layer. Preferably, the nitride layer 16 is deposited at temperatures from about 500° C. to about 700° C.

Referring to FIG. 1C, in an aspect of the present invention, the silicon/nitride containing layer 18 is then subjected to a selective dry etching process, such as reactive ion etching (RIE), using single or multiple RF power sources. The etching chemistry may include carbon and fluorine constituents formed by fluorocarbons plasma source gases. The etching chemistry may also include carbon and hydrogen constituents formed by fluorocarbon and/or hydrofluorocarbon plasma source gases. The etching chemistry may also include carbon and oxygen constituents formed by fluorocarbon and/or hydrofluorocarbon plasma source gases and O₂. The etching chemistry may additionally include carbon constituents formed by fluorocarbon and/or hydrofluorocarbon plasma source gases and an inert gas, such as nitrogen, argon, helium, or combinations thereof.

The etching process is carried out to etchback the silicon/nitride containing layer 18 followed by etching the oxide liner layer 16, to form main spacer portions e.g., 20A and 20B having outer sidewall potions e.g., B, preferably having an angle e.g., theta 1 with respect to horizontal of greater than about 75 degrees. In addition, the main spacer portions are preferably formed with an upward sloping top portion C, preferably with an angle, e.g., theta 2, with respect to horizontal that is less than or equal to theta 1. In addition a bottom portion, A, is formed having a bottom width portion of less than or equal to about 50 nm, preferably less than or equal to spacer sidewall B portion height. The overall main spacer shape thereby preferably approaches a trapezoid geometry.

The dry etching process may include a single or multiple overetch process to adjust the height of the spacers and expose a desired uppermost portion of the gate electrode 14B, having a height D, above the spacers maximum height at an inner edge. The spacer etching process, including an overetching process may be carried out to endpoint detection, for example by conventional optical or interferometer methods or may be time based.

In an important aspect of the present invention the outer sidewall portions e.g., B are formed with an angle theta 1, with respect to the horizontal plane of the substrate of between about 75 degrees and about 90 degrees, more preferably between about 80 degrees and about 90 degrees, even more preferably between about 85 degrees and about 90 degrees. The sloped angle, theta 2, of upper spacer portion C is preferably less than angle theta 1 where the top portion C slopes from a first height at an inner edge adjacent the gate electrode 14B to a lower height at an outer edge of the spacer.

In another important aspect the present invention, the trapezoid shaped spacers are formed including an overetch dry etch period where an upper portion of the spacers is etched to expose the upper sidewall portion of the gate electrode 14B where the exposed sidewall portion has a height (distance) D, protruding, above the inner edge of the spacers. Preferably, the distance D is between about 10 Angstroms and about 400 Angstroms, more preferably between about 10 Angstroms and about 60 Angstroms.

Following the spacer overetch process, a wet etching process, e.g., dilute HF, may be used to etchback oxide layer 16 portions to form spacer oxide liner portions 16A and 16B adjacent the gate electrode 14B.

Referring to Figure to FIG. 1D, following an ion implant process to form doped source/drain regions (not shown) adjacent the spacers 20A and 20B, and optionally dope the gate electrode portion 14B, a salicide formation process is then carried out to form conductive metal silicide (e.g., polycide) portions 22 at the uppermost portion of the gate electrode 14B including protruding sidewall portions having the height, D. It will be appreciated that conductive metal silicide portions may be formed over the S/D regions adjacent the spacers in the same silicide formation process. For example, a metal capable of forming a silicide, preferably titanium, cobalt or nickel, is first deposited over the gate electrode, followed by one or more annealing processes to form a low resistance silicide phase, preferably TiSi₂, CoSi₂, or NiSi. It will be appreciated that other metal suicides including PtSi or WSi₂ may be used as well.

According to the various advantages of the present invention, the formation of a protruding portion of the gate electrode a distance, D, with minimal gate electrode material loss, is important to the silicide formation process, allowing a thicker silicide portion 22, with lower series resistance (Rs) to be formed in the upper gate electrode portion. Advantageously, during the spacer overetch process to form a protruding gate electrode portion, the width of the spacers, 20A and 20B is not significantly altered, due to the trapezoidal geometry according to preferred embodiments thereby preserving spacer critical dimension (CD) and device performance. Advantageously, the distance D may be adjusted according to the method of the present invention to achieve successful formation and device performance of devices having gate lengths less than 90 nm, more preferably less than or equal to about 65 nm. In addition, advantageously, the trapezoid shaped spacers reduce or avoid preferential etching in the top portion, C of the spacers e.g., to prevent the formation of a concave upper surface, which may detrimentally affects subsequent processes, for example forming local interconnects.

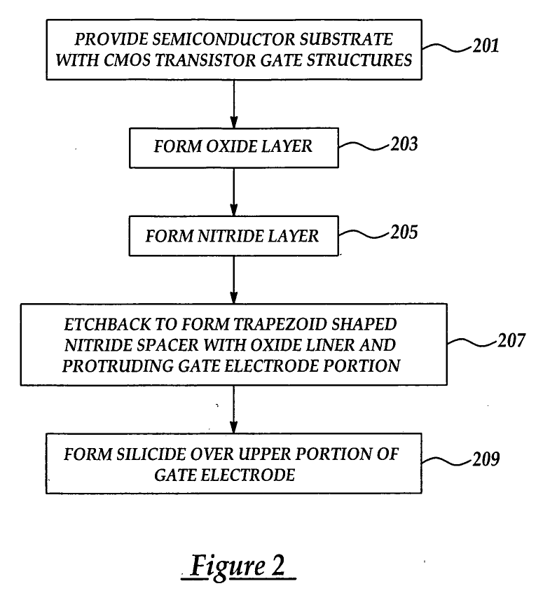

Referring to FIG. 2 is a process flow diagram including several embodiments of the present invention. In process 201, a silicon substrate including a CMOS gate structure is provided. In process 203, an overlying layer of spacer dielectric oxide is formed. In process 205, an overlying layer of spacer dielectric nitride is formed. In process 207, an etching process is carried out to form a trapezoid shaped nitride spacer with an underlying oxide liner leaving an upper portion of the gate electrode protruding above the height of the spacers. In process 209, a silicide portion is formed in the uppermost portion of the gate electrode.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A CMOS device having trapezoid shaped spacers comprising:
a semiconductor substrate;
a gate structure comprising a gate dielectric on the semiconductor substrate and a gate electrode on the gate dielectric;
trapezoid shaped spacers adjacent either side of the gate structure;
wherein, the trapezoid shaped spacers have a maximum height at an inner edge adjacent the gate electrode lower than an upper portion of the gate electrode to expose gate electrode sidewall portions.

2. The CMOS device of claim 1, wherein the exposed gate electrode sidewall portions have a height between about 10 Angstroms and about 400 Angstroms.

3. The CMOS device of claim 1, wherein the trapezoid shaped spacers comprise an outer spacer sidewall portion having an angle theta 1 greater than about 75 degrees with respect to horizontal.

4. The CMOS device of claim 3, wherein the angle theta 1 is between about 75 degrees and about 90 degrees.

5. The CMOS device of claim 3, wherein the trapezoid shaped spacers comprise an upper portion sloping upward toward the gate structure at an angle theta 2 less than angle theta 1.

6. The CMOS device of claim 3, wherein the outer spacer sidewall portion has a height greater than a width of a lower spacer portion overlying the semiconductor substrate.

7. The CMOS device of claim 1, further comprising a metal silicide disposed on the upper portion of the gate electrode, said metal silicide selected from the group consisting of TiSi₂, CoSi₂, NiSi, PtSi, and WSi.

8. The CMOS device of claim 1, wherein the trapezoid shaped spacers comprise a silicon and nitrogen containing material.

9. The CMOS device of claim 1, wherein the trapezoid shaped spacers comprise a material selected from the group consisting of silicon nitride, silicon oxynitride, and combinations thereof.

10. The CMOS device of claim 1, wherein the gate dielectric comprises a high-K dielectric having a dielectric constant greater than about 8.0.

11. The CMOS device of claim 1, further comprising a silicon oxide liner disposed between the trapezoid shaped spacers and the gate structure.

12. A CMOS device having trapezoid shaped spacers comprising:
a semiconductor substrate;
a gate structure comprising a gate dielectric on the semiconductor substrate and a gate electrode on the gate dielectric;
trapezoid shaped spacers adjacent either side of the gate structure;
wherein, the trapezoid shaped spacers have a maximum height at an inner edge adjacent the gate electrode lower than an upper portion of the gate electrode to expose gate electrode sidewall portions having an exposed height between about 10 Angstroms and about 400 Angstroms.

13. A CMOS device having trapezoid shaped spacers comprising:
a semiconductor substrate;
a gate structure comprising a high-K gate dielectric on the semiconductor substrate and a gate electrode on the gate dielectric;
trapezoid shaped spacers adjacent either side of the gate structure;
wherein, the trapezoid shaped spacers have a maximum height at an inner edge adjacent the gate electrode lower than an upper portion of the gate electrode to expose gate electrode sidewall portions having an exposed height between about 10 Angstroms and about 400 Angstroms.

14. A method of forming a CMOS device having trapezoid shaped spacers comprising the steps of:
providing semiconductor substrate;
forming gate structure comprising a gate dielectric on the semiconductor substrate and a gate electrode on the gate dielectric;
forming trapezoid shaped spacers adjacent either side of the gate structure;
wherein, the trapezoid shaped spacers are formed to have a maximum height at an inner edge adjacent the gate electrode lower than an upper portion of the gate electrode to expose gate electrode sidewall portions.

15. The method of claim 14, wherein the exposed gate electrode sidewall portions have a height between about 10 Angstroms and about 400 Angstroms.

16. The method of claim 14, wherein the trapezoid shaped spacers comprise an outer spacer sidewall portion having an angle theta 1 greater than about 75 degrees with respect to horizontal.

17. The method of claim 16, wherein the angle theta 1 is between about 75 degrees and about 90 degrees.

18. The method of claim 16, wherein the trapezoid shaped spacers comprise an upper portion sloping upward toward the gate structure at an angle theta 2 less than angle theta 1.

19. The method of claim 16, wherein the outer spacer sidewall portion has a height greater than a width of a lower spacer portion overlying the semiconductor substrate.

20. The method of claim 14, further comprising the step of forming a metal silicide on the upper portion of the gate electrode, said metal silicide selected from the group consisting of TiSi₂, CoSi₂, NiSi, PtSi, and WSi.

21. The method of claim 14 wherein the trapezoid shaped spacers comprise a silicon and nitrogen containing material.

22. The method of claim 14, further comprising forming the trapezoid shaped spacers with a silicon oxide liner disposed between the trapezoid shaped spacers and the gate structure.

23. The method of claim 14, wherein the step of forming trapezoid shaped spacers etching comprises a dry etching process having an etching chemistry components selected from the group consisting of carbon, fluorine, hydrogen, oxygen, and an inert gas.

24. A method of forming a CMOS device having trapezoid shaped spacers comprising the steps of:
providing semiconductor substrate;
forming gate structure comprising a gate dielectric on the semiconductor substrate and a gate electrode on the gate dielectric;
forming trapezoid shaped spacers adjacent either side of the gate structure;
wherein, the trapezoid shaped spacers are formed to have a maximum height at an inner edge adjacent the gate electrode lower than an upper portion of the gate electrode to expose gate electrode sidewall portions having an exposed height between about 10 Angstroms and about 400 Angstroms.
